(19) United States
(12) Patent Application Publication
(10) Pub. No.: US 2020/0351791 A1
(43) Pub. Date: Nov. 5, 2020

(54) Low-Power Connected Mode in Wireless Communication Systems

(71) Applicant: Google LLC, Mountain View, CA (US)

(72) Inventors: Erik Richard Stauffer, Sunnyvale, CA (US); Jibing Wang, San Jose, CA (US)

(73) Assignee: Google LLC, Mountain View, CA (US)

(21) Appl. No.: 16/957,364

(22) PCT Filed: Aug. 6, 2019
(86) PCT No.: PCT/US2019/045356

§ 371 Date: Jun. 23, 2020

Related U.S. Application Data
(60) Provisional application No. 62/729,289, filed on Sep. 10, 2018.

(51) Int. Cl. H04W 52/02; H04W 76/27; H04W 24/08; H04W 80/02; H04W 72/04; H04W 28/02

(52) U.S. Cl. CPC H04W 52/0274; H04W 76/27; H04W 24/08; G01R 31/382; H04W 72/0413; H04W 28/0221; H04W 80/02

(57) ABSTRACT

This document describes methods, devices, systems, and means for a low-power connected mode for wireless communication systems. In aspects, a user equipment (110) detects a thermal state or a battery state-of-charge while operating in a Radio Resource Control (RRC) connected mode (302). Based on the thermal state or the battery state-of-charge, the user equipment (110) transmits a request message to a base station (120) to request to enter into a low-power connected mode (304). The user equipment (110) receives a configuration message from the base station (120) to activate the low-power connected mode (306). The user equipment (110) then activates the low-power connected mode (308). Activating the low-power connected mode enables the user equipment (110) to reduce the thermal state and power consumption by maintaining an RRC connection with reduced functionalities, such as without monitoring a downlink channel for downlink signals from the base station (120).

### BACKGROUND

The evolution of wireless communication to fifth generation (5G) standards and technologies provides higher data rates and greater capacity with improved reliability and lower latency, which enhances mobile broadband services. 5G technologies also provide new classes of service for vehicular networking, fixed wireless broadband, and the Internet of Things (IoT).

With higher data rates, a user equipment (UE) may consume more power and generate more heat. For example, the UE may heat up to temperatures that can damage one or more physical components of the UE and/or temperatures that are uncomfortable for a user holding or in contact with the UE. Additionally, when using these higher data rates, the UE may consume battery power beyond a critical level. These thermal and power issues may reduce the lifespan of the UE.

### SUMMARY

This summary is provided to introduce simplified concepts of a low-power connected mode for wireless communication systems. The simplified concepts are further described below in the Detailed Description. This summary is not intended to identify essential features of the claimed subject matter nor is it intended for use in determining the scope of the claimed subject matter.

This document describes methods, devices, systems, and means for a low-power connected mode for wireless communication systems. In aspects, a user equipment detects a thermal state or a battery state-of-charge while operating in a Radio Resource Control (RRC) connected mode. Based on the thermal state or the battery state-of-charge, the user equipment transmits a request message to a base station to request to enter into a low-power connected mode. The user equipment receives a configuration message from the base station to activate the low-power connected mode. The user equipment then activates the low-power connected mode. Activating the low-power connected mode enables the user equipment to reduce the thermal state and power consumption by maintaining an RRC connection with reduced functionalities, such as without monitoring a downlink channel for downlink signals from the base station. To exit the low-power connected mode, the user equipment transmits a cancel message to the base station via a physical layer (e.g., physical uplink control channel or random access channel) to inform the base station that the user equipment is going to change modes. After sending the cancel message, the user equipment resumes normal operation of the RRC connected mode.

The details of one or more implementations are set forth in the accompanying drawings and the following description. Other features and advantages will be apparent from the description and drawings, and from the claims. This summary is provided to introduce subject matter that is further described in the Detailed Description and Drawings. Accordingly, this summary should not be considered to describe essential features nor used to limit the scope of the claimed subject matter.

### BRIEF DESCRIPTION OF THE DRAWINGS

Aspects of a low-power connected mode for wireless communication systems are described with reference to the following drawings. The same numbers are used throughout the drawings to reference like features and components:

FIG. 1 illustrates an example wireless network environment in which various aspects of a low-power connected mode for wireless communication systems can be implemented.

FIG. 2 illustrates an example device diagram for devices that can implement various aspects of a low-power connected mode for wireless communication systems.

FIG. 3 illustrates an example method of controlling connection modes in a user equipment in accordance with aspects of the techniques described herein.

FIG. 4 illustrates an example method of enabling user equipment-controlled connected modes in accordance with aspects of the techniques described herein.

### DETAILED DESCRIPTION

Overview

This document describes methods, devices, systems, and means for a low-power connected mode for wireless communication systems. Generally, a base station is unaware of certain issues occurring at the user equipment, such as a thermal state that could potentially damage the user equipment or a battery status that could be critically low. Consequently, the base station is not capable of responding to these issues as they occur, which could otherwise mitigate negative effects of thermal or power issues at the user equipment.

Providing the user equipment with the capability to inform the base station of these issues as they occur, and the flexibility to select a different operational mode, can substantially mitigate the issues and extend the life of the user equipment (both the battery life cycle and the overall life of components of the user equipment that could be damaged by high temperatures). Accordingly, the user equipment can transmit a request to the base station to request to enter into a low-power connected mode to reduce performance of some functions that may cause heat to be created and/or drain battery power past critical levels. This mode is a low-power state of the RRC connected mode. For instance, the user equipment maintains an RRC connection while in the low-power connected mode, but conserves power by disabling (not performing) certain functions, such as monitoring of a downlink channel for downlink signals from the base station.

After a duration of time, at a scheduled time, or at a triggered time (e.g., after the user equipment has returned to normal operating temperatures or has been connected to an alternate power source), the user equipment can transmit a cancel message to the base station to inform the base station that the user equipment is returning to the RRC connected mode. Because the user equipment maintained the RRC connection during the low-power connected mode, the user equipment does not transmit the cancel message via an RRC message to establish a new RRC connection. Rather, the user equipment uses a dedicated physical layer procedure to transmit the cancel message, such as using a physical uplink control channel (PUCCH) or a random access channel (RACH). Then, the user equipment can simply resume normal operation of the RRC connected mode using the same RRC connection and allocated channels.

These techniques reduce delays typically caused by communications between the user equipment and the base station when attempting to establish an RRC connection, such as when changing the user equipment from an RRC idle mode or RRC inactive mode to the RRC connected mode. These techniques also reduce network overhead used and power consumed by attempting to switch from the RRC idle mode or the RRC inactive mode to the RRC connected mode.

While features and concepts of the described methods, devices, systems, and means for a low-power connected mode for wireless communication systems can be implemented in any number of different environments, systems, devices, and/or various configurations, aspects of the a low-power connected mode for wireless communication systems are described in the context of the following example devices, systems, and configurations.

Example Environment

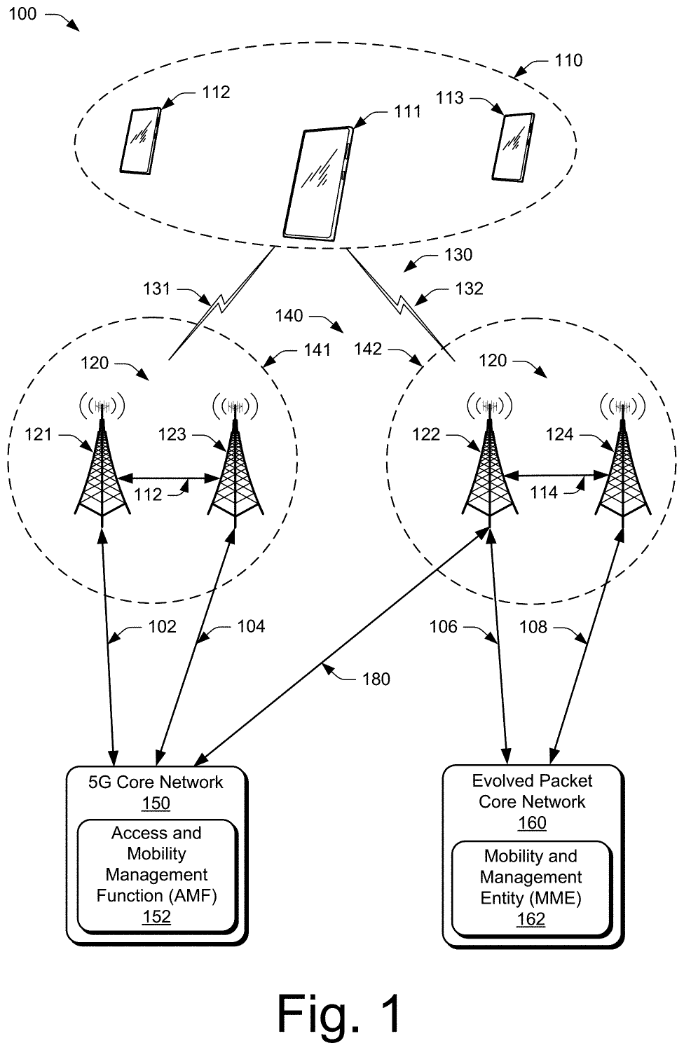

FIG. 1 illustrates an example environment 100, which includes multiple user equipment 110 (UE 110), illustrated as UE 111, UE 112, and UE 113. Each UE 110 can communicate with one or more base stations 120 (illustrated as base stations 121, 122, 123, and 124) through one or more wireless communication links 130 (wireless link 130), illustrated as wireless links 131 and 132. In this example, the UE 110 is implemented as a smartphone. Although illustrated as a smartphone, the UE 110 may be implemented as any suitable computing or electronic device, such as a mobile communication device, a modem, cellular phone, gaming device, navigation device, media device, laptop computer, desktop computer, tablet computer, smart appliance, vehicle-based communication system, and the like. The base stations 120 (e.g., an Evolved Universal Terrestrial Radio Access Network Node B, E-UTRAN Node B, evolved Node B, eNodeB, eNB, Next Generation Node B, gNode B, gNB, or the like) may be implemented in a macrocell, microcell, small cell, picocell, or the like, or any combination thereof.

The base stations 120 communicate with the UE 110 via the wireless links 131 and 132, which may be implemented as any suitable type of wireless link. The wireless link 131 and 132 can include a downlink of data and control information communicated from the base stations 120 to the UE 110, an uplink of other data and control information communicated from the UE 110 to the base stations 120, or both. The wireless links 130 may include one or more wireless links or bearers implemented using any suitable communication protocol or standard, or combination of communication protocols or standards such as 3rd Generation Partnership Project Long-Term Evolution (3GPP LTE), Fifth Generation New Radio (5G NR), and so forth. Multiple wireless links 130 may be aggregated in a carrier aggregation to provide a higher data rate for the UE 110. Multiple wireless links 130 from multiple base stations 120 may be configured for Coordinated Multipoint (CoMP) communication with the UE 110. Additionally, multiple wireless links 130 may be configured for single-RAT dual connectivity or multi-RAT dual connectivity (MR-DC). Each of these various multiple-link situations tends to increase the power consumption of the UE 110.

The base stations 120 are collectively a Radio Access Network 140 (RAN, Evolved Universal Terrestrial Radio Access Network, E-UTRAN, 5G NR RAN or NR RAN). The RANs 140 are illustrated as a NR RAN 141 and an E-UTRAN 142. The base stations 121 and 123 in the NR RAN 141 are connected to a Fifth Generation Core 150 (5GC 150) network. The base stations 122 and 124 in the E-UTRAN 142 are connected to an Evolved Packet Core 160 (EPC 160). Optionally or additionally, the base station 122 may connect to both the 5GC 150 and EPC 160 networks.

The base stations 121 and 123 connect, at 102 and 104 respectively, to the 5GC 150 via an NG2 interface for control-plane signaling and via an NG3 interface for user-plane data communications. The base stations 122 and 124 connect, at 106 and 108 respectively, to the EPC 160 via an S1 interface for control-plane signaling and user-plane data communications. Optionally or additionally, if the base station 122 connects to the 5GC 150 and EPC 160 networks, the base station 122 connects to the 5GC 150 via an NG2 interface for control-plane signaling and via an NG3 interface for user-plane data communications, at 180.

In addition to connections to core networks, base stations 120 may communicate with each other. The base stations 121 and 123 communicate via an Xn interface at 112. The base stations 122 and 124 communicate via an X2 interface at 114.

The 5GC 150 includes an Access and Mobility Management Function 152 (AMF 152) that provides control-plane functions such as registration and authentication of multiple UE 110, authorization, mobility management, or the like in the 5G NR network. The EPC 160 includes a Mobility Management Entity 162 (MME 162) that provides control-plane functions such as registration and authentication of multiple UE 110, authorization, mobility management, or the like in the E-UTRA network. The AMF 152 and the MME 162 communicate with the base stations 120 in the RANs 140 and also communicate with multiple UE 110, via the base stations 120.

Example Devices

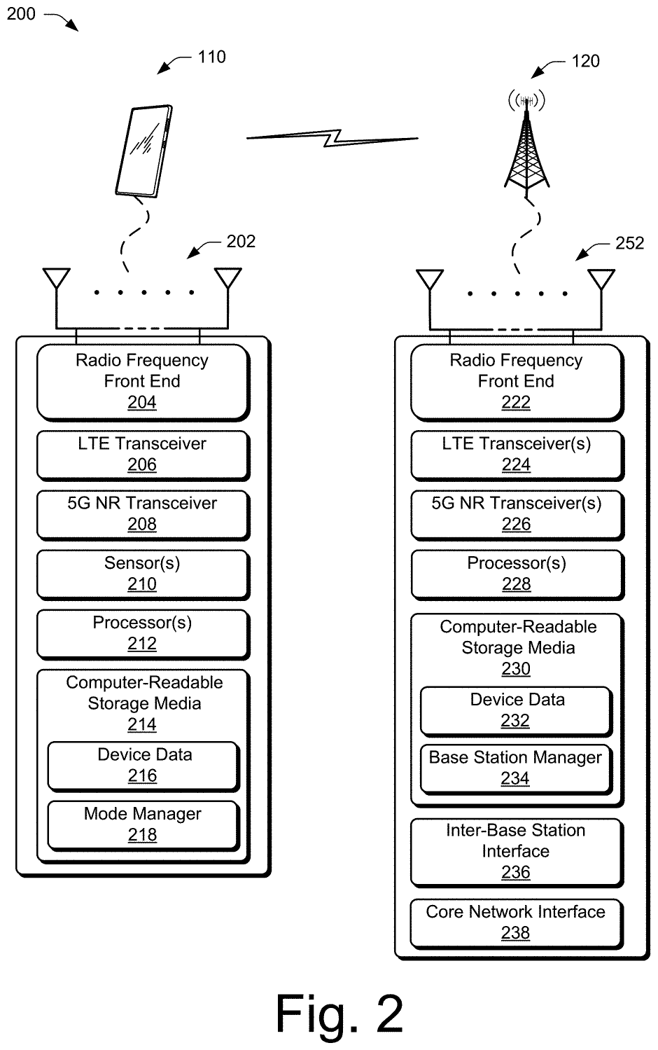

FIG. 2 illustrates an example device diagram 200 for devices that can implement various aspects of a low-power connected mode for wireless communication systems. Included in FIG. 2 are the multiple UE 110 and the base stations 120. The multiple UE 110 and the base stations 120 may include additional functions and interfaces that are omitted from FIG. 2 for the sake of clarity. The UE 110 includes antennas 202, a radio frequency front end 204 (RF front end 204), and radio frequency transceivers (e.g., an LTE transceiver 206 and a 5G NR transceiver 208) for communicating with base stations 120 in the 5G RAN 141 and/or the E-UTRAN 142. The RF front end 204 of the UE 110 can couple or connect the LTE transceiver 206, and the 5G NR transceiver 208 to the antennas 202 to facilitate various types of wireless communication.

The antennas 202 of the UE 110 may include an array of multiple antennas that are configured similar to or differently from each other. The antennas 202 and the RF front end 204 can be tuned to, and/or be tunable to, one or more frequency bands defined by the 3GPP LTE and 5G NR communication standards and implemented by the LTE transceiver 206, and/or the 5G NR transceiver 208. Additionally, the antennas 202, the RF front end 204, the LTE transceiver 206, and/or the 5G NR transceiver 208 may be configured to support beamforming for the transmission and reception of communications with the base stations 120. By way of example and not limitation, the antennas 202 and the RF front end 204 can be implemented for operation in sub-gigahertz bands, sub-6 GHz bands, and/or above 6 GHz bands that are defined by the 3GPP LTE and 5G NR communication standards.

The UE 110 includes sensor(s) 210 can be implemented to detect various properties such as temperature, supplied power, power usage, battery state-of-charge, or the like. As such, the sensors 210 may include any one or a combination of temperature sensors, thermistors, battery sensors, and power usage sensors.

The UE 110 also includes processor(s) 212 and computer-readable storage media 214 (CRM 214). The processor 212 may be a single core processor or a multiple core processor composed of a variety of materials, such as silicon, polysilicon, high-K dielectric, copper, and so on. The computer-readable storage media described herein excludes propagating signals. CRM 214 may include any suitable memory or storage device such as random-access memory (RAM), static RAM (SRAM), dynamic RAM (DRAM), non-volatile RAM (NVRAM), read-only memory (ROM), or Flash memory useable to store device data 216 of the UE 110. The device data 216 includes user data, multimedia data, beamforming codebooks, applications, and/or an operating system of the UE 110, which are executable by processor(s) 212 to enable user-plane communication, control-plane signaling, and user interaction with the UE 110.

CRM 214 also includes a mode manager 218. Alternately or additionally, the mode manager 218 may be implemented in whole or part as hardware logic or circuitry integrated with or separate from other components of the UE 110. In at least some aspects, the mode manager 218 configures the RF front end 204, the LTE transceiver 206, and/or the 5G NR transceiver 208 to implement the techniques for a low-power connected mode described herein.

The device diagram for the base stations 120, shown in FIG. 2, includes a single network node (e.g., a gNode B). The functionality of the base stations 120 may be distributed across multiple network nodes or devices and may be distributed in any fashion suitable to perform the functions described herein. The base stations 120 include antennas 220, a radio frequency front end 222 (RF front end 222), one or more LTE transceivers 224, and/or one or more 5G NR transceivers 226 for communicating with the UE 110. The RF front end 222 of the base stations 120 can couple or connect the LTE transceivers 224 and the 5G NR transceivers 226 to the antennas 220 to facilitate various types of wireless communication. The antennas 220 of the base stations 120 may include an array of multiple antennas that are configured similar to or differently from each other. The antennas 220 and the RF front end 222 can be tuned to, and/or be tunable to, one or more frequency band defined by the 3GPP LTE and 5G NR communication standards, and implemented by the LTE transceivers 224, and/or the 5G NR transceivers 226. Additionally, the antennas 220, the RF front end 222, the LTE transceivers 224, and/or the 5G NR transceivers 226 may be configured to support beamforming, such as Massive-MIMO, for the transmission and reception of communications with the UE 110.

The base stations 120 also include processor(s) 228 and computer-readable storage media 230 (CRM 230). The processor 228 may be a single core processor or a multiple core processor composed of a variety of materials, such as silicon, polysilicon, high-K dielectric, copper, and so on. CRM 230 may include any suitable memory or storage device such as random-access memory (RAM), static RAM (SRAM), dynamic RAM (DRAM), non-volatile RAM (NVRAM), read-only memory (ROM), or Flash memory useable to store device data 232 of the base stations 120. The device data 232 includes network scheduling data, radio resource management data, beamforming codebooks, applications, and/or an operating system of the base stations 120, which are executable by processor(s) 228 to enable communication with the UE 110.

CRM 230 also includes a base station manager 234. Alternately or additionally, the base station manager 234 may be implemented in whole or part as hardware logic or circuitry integrated with or separate from other components of the base stations 120. In at least some aspects, the base station manager 234 configures the LTE transceivers 224 and the 5G NR transceivers 226 for communication with the UE 110, as well as communication with a core network. The base stations 120 include an inter-base station interface 236, such as an Xn and/or X2 interface, which the base station manager 234 configures to exchange user-plane and control-plane data between another base station 120, to manage the communication of the base stations 120 with the UE 110. The base stations 120 include a core network interface 238 that the base station manager 234 configures to exchange user-plane and control-plane data with core network functions and entities.

Immediate Low-Power Connected Mode

The low-power connected mode is a low-power state of the RRC connected mode but can be considered as a separate RRC mode. The low-power connected mode is not an idle mode, such as an RRC idle mode, which is triggered by the network or the base station, no RRC connection is established, and a resume message is required to return to the connected mode. Rather, the low-power connected mode is triggered by the user equipment 110 and includes one or more disabled or paused RRC-connected-mode operations. For instance, when the user equipment 110 is operating in the low-power connected mode, the user equipment 110 maintains an RRC connection with a particular carrier but does not perform (e.g., disables, pauses, prevents execution of, or turns off) certain functions of the RRC connected mode that, through execution by the processor 212, use a large amount of power and/or cause the processor 212 or one or more other components of the user equipment 110 to increase in temperature. The RRC connection includes having a dedicated physical channel allocated to the user equipment 110 in uplink and downlink. The dedicated physical channel may be a physical uplink control channel (PUCCH) or a random access channel (RACH) dedicated to the purpose of communicating with the base station regarding a change in RRC modes, e.g., from immediate low-power connected mode to RRC connected mode.

The low-power connected mode may be used in situations that are critical (e.g., critically-high thermal state, critically-low battery state) for the user equipment 110. These situations may be considered “emergency” situations and may require immediate mitigation to prevent component damage or memory loss.

One example function that may be disabled or paused during the low-power connected mode is monitoring a downlink channel for downlink signals from the base station 120. Generally, a user equipment 110 in the RRC connected mode monitors the downlink channel on a subframe-by-subframe basis, such as every millisecond. However, if the user equipment 110 is communicating with high data transfer rates, such as 5 Gbps or 10 Gbps, the thermal state of the user equipment 110 may increase above a threshold temperature or the battery charge level may decrease below a threshold level, such as a critical level. Accordingly, the low-power connected mode allows the user equipment 110 to maintain an RRC connection without performing some of the resource-heavy functions.

A benefit of maintaining the RRC connection in a low-power mode is to simplify and speed up the reconnection procedure. This is beneficial because the base station 120 that typically controls the wireless communications with the user equipment 110 is unaware of the thermal and battery issues at the user equipment 110, unless the user equipment 110 informs the base station 120. Further, using conventional systems that place the user equipment 110 in the RRC idle mode, each time the user equipment 110 transitions from the RRC idle mode to the RRC connected mode, additional signaling is used, which causes additional overhead on the network, introduces delays for the communications, and results in associated power consumption. In contrast to these conventional systems, the low-power connected mode allows the user equipment 110 to resume normal operation of the RRC connection by resuming, restarting, initiating, or enabling full functionality of the RRC connection. The RRC connection does not need to be re-established because the RRC connection was maintained throughout the duration of the low-power connected mode. Therefore, the user equipment 110 simply resumes the functions that were disabled during the low-power connected mode.

Before enabling those functions, however, the user equipment 110 informs the base station 120 by sending a cancel message via a physical layer to indicate that the user equipment 110 is exiting the low-power connected mode and resuming normal operation in the RRC connected mode for one or more carriers. This allows the base station 120 to be aware that the user equipment 110 is able to receive communications from the base station 120.

In aspects, the low-power connected mode can be enabled or canceled on a per-carrier basis. In an example, the user equipment 110 may be connected with a low-band carrier (e.g., sub-6 GHz carrier frequency) with a small 20 MHz bandwidth and a millimeter-wave (mm-wave) carrier (e.g., 30-300 GHz carrier frequency) that has an 800 MHz bandwidth. Here, the 800 MHz mm-wave carrier may cause thermal or power consumption concerns. Accordingly, the user equipment 110 may select to activate the low-power connected mode for only the mm-wave carrier but not for the low-band carrier. In this way, the user equipment 110 can specify different modes for different carriers.

Example Methods

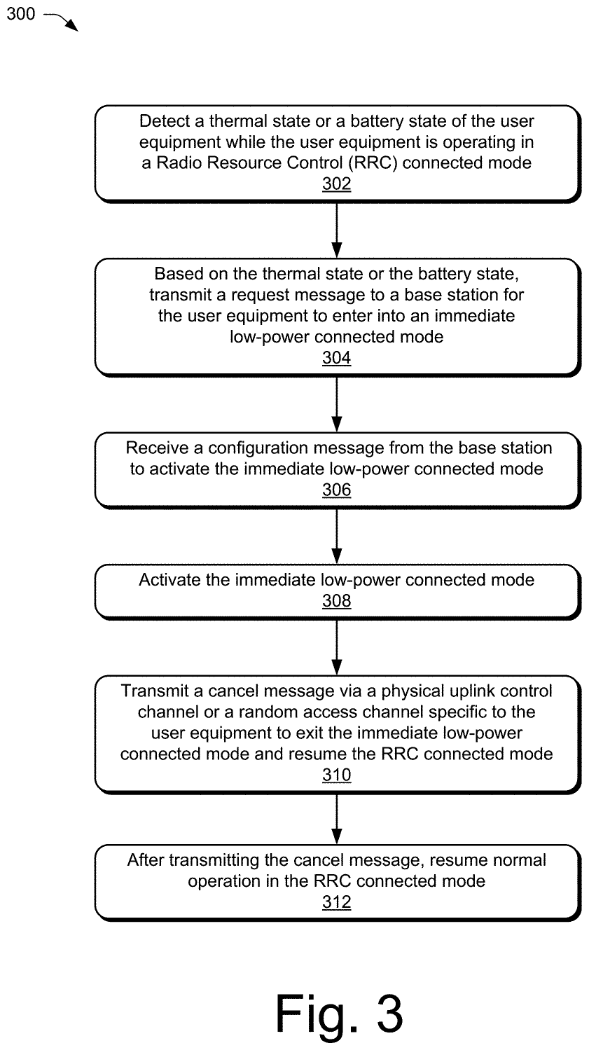

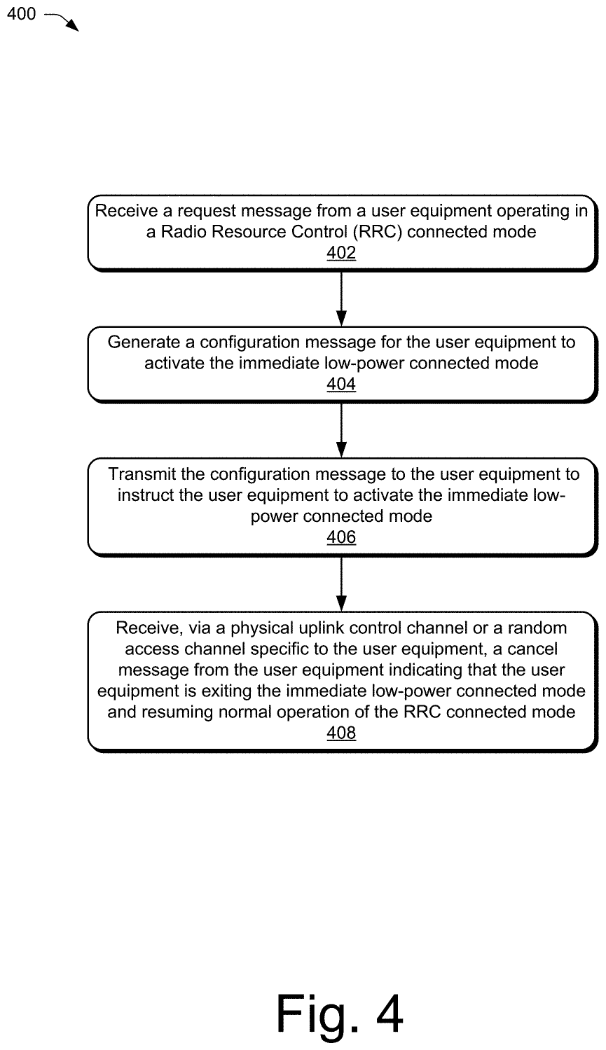

Example methods 300 and 400 are described with reference to FIGS. 3 and 4 in accordance with one or more aspects of a low-power connected mode for wireless communication systems.

FIG. 3 illustrates example method(s) 300 of controlling operational modes in a user equipment in accordance with aspects of the techniques described herein. At 302, a user equipment detects a thermal state or a battery state-of-charge of the user equipment while operating in a Radio Resource Control (RRC) connected mode. For example, the user equipment 110 of FIG. 2 uses signals from one or more sensors 210, such as a temperature sensor, to detect a thermal state of the user equipment 110. The thermal state may indicate a temperature of one or more components of the user equipment 110. In some instances, the one or more components of the user equipment 110 may have a temperature that is elevated above normal operating temperatures due to a rate of data transfer, such as if the user equipment is communicating at a rate of 5 Gbps or 10 Gbps. One drawback of high rates of data processing is the creation of heat, which can increase the temperature of various components of the user equipment 110 or the overall temperature of the user equipment 110 itself

In implementations, the user equipment 110 can compare the thermal state to a threshold temperature value to determine whether to trigger a request to activate the low-power connected mode. Some example threshold temperatures can include predefined temperatures, such as 100° F., 120° F., 150° F., and so on. Alternatively or additionally, the threshold temperatures can include a predefined temperature above an expected operating temperature, e.g., 20° F., 30° F., or 40° F. above the expected operating temperature. These high temperatures may not only be damaging to various components and circuitry of the user equipment 110 but may also be uncomfortable for a user holding the user equipment 110.

Alternatively or additionally, the user equipment 110 uses signals from one or more sensors 210, such as battery sensors, to detect a state of a battery of the user equipment. For example, the charge level of the battery may be approaching a critically-low level from extended use of the user equipment 110 without recent recharging or from processing large payloads. One drawback of high rates of data processing is the consumption of power, particularly battery power for a user equipment relying on a battery for power. The battery sensors may detect a state of the battery, such as a charge level, e.g., 50%, 30%, 10%, 2%, and so on.

In aspects, the user equipment 110 can compare the battery state-of-charge to a threshold value, such as a predefined value representing a charge level of the battery, to determine whether to trigger a request to activate the low-power connected mode. Some example threshold values include 50%, 30%, 15%, 10%, 5%, 2%, and so on. Any suitable threshold value can be used to represent a charge level of the battery usable to trigger a request to activate the low-power connected mode.

At 304, the user equipment transmits, based on the thermal state or the battery state-of-charge, a request message to a base station for the user equipment to enter into a low-power connected mode. For example, if the thermal state is greater than the threshold temperature value, or if the battery state-of-charge is lower than the threshold charge level, the user equipment 110 triggers a request message to be sent to the base station 120. The request message includes a request to enter into a low-power connected mode, which enables the user equipment 110 to maintain an RRC connection without monitoring a downlink channel for downlink signals from the base station 120. In this way, the user equipment 110 triggers the low-power, which is a low-power state of the RRC connected mode in which one or more operations of the RRC connected mode are paused or disabled. Accordingly, without monitoring the downlink channel for a duration of time, the user equipment 110 reduces the load on the processor 212, which may allow for accumulated heat to dissipate. The reduction of the load on the processor 212 also reduces power consumption, which conserves battery power and extends the life cycle of the battery.

In aspects, the user equipment 110 transmits the request message using any suitable communication technique appropriate to the RRC connected mode. For example, the user equipment 110 may transmit the request message using an RRC message. Alternatively, the user equipment 110 may transmit the request message using a medium access control-control element (MAC-CE). Another alternative technique includes the user equipment 110 transmitting the request message using uplink control information (UCI) on a PUCCH. The request message may also be sent via a supplementary uplink (SUL) or a Long-Term Evolution (LTE) uplink.

In some implementations, the request message identifies one or more carriers for which the user equipment 110 is requesting to activate the low-power connected mode. In this way, the low-power connected mode can be activated on a per-carrier basis, at the request of the user equipment 110.

The request message can also indicate a duration of time for the low-power connected mode to be activated, such as 10 ms, 100 ms, 1.0 second, 10 seconds, 30 seconds, one minute, five minutes, and so on. Any suitable duration of time can be used to provide the user equipment 110 sufficient time to cool down, or to provide the user sufficient time to locate and connect the user equipment 110 to an alternative power source, such as direct current (DC) power or a portable power bank. Alternatively, the request message can indicate an end-time for which the user equipment is scheduled to exit the low-power connected mode and resume normal operation of the RRC connected mode. In aspects, the end-time can be represented by a set time, such as 3:03 pm, 10:00 am, or any other set time that provides a sufficient amount of time to cool down or to provide the user with time to locate and connect the user equipment 110 to an alternative power source.

In aspects, the request message is transmitted via a different uplink carrier from the carrier for which the low-power connected mode is to be activated. Accordingly, different carrier uplinks can be used to request the low-power connected mode. For example, the user equipment 110 can use a low-band carrier to transmit the request message to enter the low-power connected mode for a mm-wave carrier. In another example, the user equipment 110 can use a mm-wave carrier to transmit the request message to enter the low-power connected mode for a low-band carrier.

At 306, the user equipment receives a configuration message from the base station to activate the a low-power connected mode. For example, the user equipment 110 receives the configuration message from the base station 120, via the wireless link 130, acknowledging the request message.

At 308, the user equipment activates the low-power connected mode. For example, the user equipment 110 activates the low-power connected mode to reduce both the thermal state and power consumption of the user equipment by maintaining the RRC connection without monitoring the downlink channel for downlink signals from the base station. In aspects, the low-power connected mode is a low-power state of the RRC connected mode in which the user equipment 110 maintains the RRC connection but disables or prevents certain operations from being executed, such as the monitoring of the downlink channel.

Monitoring the downlink channel can require processing power that results in the creation of heat as a byproduct, which can cause damage if not regulated. However, maintaining the RRC connection makes the process of re-establishing the RRC connected mode much faster and simpler than in conventional techniques that require an RRC message to change to a different mode, e.g., from an RRC idle mode to the RRC connected mode. Rather, these techniques enable the user equipment 110 to send a low layer message, such as a RACH message or a UCI physical layer message, resulting in a faster turnaround time to communicate and establish the RRC connected mode. For example, using conventional techniques to change modes from the RRC idle mode to the RRC connected mode, additional signaling is required, causing additional overhead of the network and introducing delays for user equipment communication. There may also be associated power consumption each time the user equipment switches modes from connected to idle and back to connected.

Subsequently, at 310, the user equipment 110 transmits a cancel message via a PUCCH or a RACH specific to the user equipment to exit the low-power connected mode and resume the RRC connected mode. The cancel message enables the user equipment 110 to control when it exits the low-power connected mode. In aspects, the cancel message is transmitted via a different uplink carrier from the carrier for which the low-power connected mode has been activated. Accordingly, different carrier uplinks can be used to cancel the low-power connected mode. For example, the user equipment 110 can use the sub-6 carrier to transmit the cancel message to exit the low-power connected mode for the 30-300 GHz mm-wave carrier.

At 312, after transmitting the cancel message, the user equipment 110 resumes normal operation in the RRC connected mode. For example, the user equipment 110 may begin monitoring the downlink channel for downlink signals from the base station 120.

FIG. 4 illustrates example method(s) 400 of enabling user equipment-controlled connected modes in accordance with aspects of the techniques described herein. At 402, the base station receives a request message from the user equipment operating in a Radio Resource Control (RRC) connected mode. In aspects, the request message is received via an RRC message, a MAC-CE, or a UCI. The request message requests activation of a low-power connected mode based on a thermal state or a battery state-of-charge of the user equipment 110. In this way, the user equipment 110 informs the base station 120 that there is an issue with the thermal state or the battery state-of-charge of the user equipment 110 that requires mitigation, such as reducing a temperature of the user equipment 110 and/or conserving battery power.

At 404, the base station generates a configuration message for the user equipment to activate the low-power connected mode. In aspects, the configuration message includes a recommended end-time for the user equipment 110 to exit the low-power connected mode and resume normal operation of the RRC connected mode. The recommended end-time may or may not coincide with the time indicated in the request message. Rather, the base station 120 may recommend a different time or duration of time based on scheduling conflicts. The recommended time indicates to the user equipment 110 a time when the base station 120 can synchronize with the user equipment 110. The user equipment 110 may exit the low-power connected mode at either the recommended time or a different time, such as the time indicated by the user equipment 110. The base station 120 may, however, use the recommended time to begin transmitting signals to the user equipment 110.

At 406, the base station transmits the configuration message to the user equipment to instruct the user equipment to activate the low-power connected mode. In at least one example, the configuration message instructs the user equipment to activate the low-power connected mode for one or more specific carriers that are identified in the request message. The base station 120 may delay communications with the user equipment 110 while the low-power connected mode is activated at the user equipment 110 since the base station 120 is aware that the user equipment 110 is not monitoring the downlink channel. The base station 120 may delay communications for a specific carrier for which the low-power connected mode is activated. The delayed communications may be stored and aggregated by the base station 120 until the user equipment 110 exits the low-power connected mode.

At 408, the base station receives, via a PUCCH or RACH specific to the user equipment, a cancel message from the user equipment indicating that the user equipment is exiting the low-power connected mode and resuming normal operation of the RRC connected mode. The cancel message also identifies particular carrier(s) for which the RRC connected mode is to be resumed with the user equipment 110. In aspects, the cancel message is received via a different uplink carrier from the carrier for which the low-power connected mode has been activated. In another example, the cancel message may be received via a supplementary uplink (SUL) or an LTE uplink.

The order in which the method blocks of FIGS. 3 and 4 are described are not intended to be construed as a limitation, and any number of the described method blocks can be combined, skipped, or repeated in any order to implement a method, or an alternate method.

Generally, any of the components, modules, methods, and operations described herein can be implemented using software, firmware, hardware (e.g., fixed logic circuitry), manual processing, or any combination thereof. Some operations of the example methods may be described in the general context of executable instructions stored on computer-readable storage memory that is local and/or remote to a computer processing system, and implementations can include software applications, programs, functions, and the like. Alternatively or in addition, any of the functionality described herein can be performed, at least in part, by one or more hardware logic components, such as, and without limitation, Field-programmable Gate Arrays (FPGAs), Application-specific Integrated

Circuits (ASICs), Application-specific Standard Products (ASSPs), System-on-a-chip systems (SoCs), Complex Programmable Logic Devices (CPLDs), and the like.

In the following, several examples are described.

### EXAMPLE 1

A method of controlling operational modes in a user equipment, the method comprising: detecting a thermal state or a battery state-of-charge of the user equipment while the user equipment is operating in a Radio Resource Control connected mode; based on the thermal state or the battery state-of-charge, transmitting a request message to a base station for the user equipment to enter into a low-power connected mode, the request message identifying a particular carrier, the low-power connected mode enabling the user equipment to maintain an RRC connection without monitoring a downlink channel for downlink signals from the base station; receiving a configuration message from the base station to activate the low-power connected mode; and activating the low-power connected mode for the particular carrier by the user equipment.

### EXAMPLE 2

The method as described in example 1, wherein transmitting the request message comprises transmitting the request message to the base station using a Radio Resource Control message, a medium access control-control element, or uplink control information.

### EXAMPLE 3

The method as described in any one of example 1 or example 2, wherein the request message is transmitted using an uplink carrier different from the particular carrier.

### EXAMPLE 4

The method as described in any one of the preceding examples, wherein activating the low-power connected mode comprises activating the low-power connected mode for the particular carrier while maintaining a Radio Resource Control connected mode using a second carrier.

### EXAMPLE 5

The method as described in any one of the preceding examples, wherein the request message indicates a duration of time for the low-power connected mode to be activated.

### EXAMPLE 6

The method as described in any one of examples 1 to 4, wherein the request message indicates an end-time for the low-power connected mode.

### EXAMPLE 7

The method as described in any one of the preceding examples, further comprising transmitting a cancel message to exit the low-power connected mode and enter the Radio Resource Control connected mode.

### EXAMPLE 8

The method as described in example 7, wherein the cancel message is transmitted via a physical uplink control channel.

### EXAMPLE 9

The method as described in example 7, wherein the cancel message is transmitted via a random access channel specific to the user equipment.

### EXAMPLE 10

The method as described in any one of the preceding examples, wherein the request message is transmitted using a supplementary uplink or a Long-Term Evolution Uplink.

### EXAMPLE 11

A user equipment comprising: a radio frequency transceiver for communicating with a base station; a temperature sensor for detecting a temperature of the user equipment; and a processor and memory system, coupled to the radio frequency transceiver and the temperature sensor, configured to perform the method of any one of examples 1 to 10.

### EXAMPLE 12

A method for enabling user equipment-controlled connection modes, the method comprising: receiving, by a base station, a request message from a user equipment operating in a Radio Resource Control connected mode, the request message requesting activation of a low-power connected mode for at least one particular carrier, the low-power connected mode comprising a low-power state of the Radio Resource Control connected mode in which the user equipment does not monitor for downlink signals from the base station; generating, by the base station, a configuration message for the user equipment to activate the low-power connected mode for the particular carrier; and transmitting, by the base station, the configuration message to the user equipment.

### EXAMPLE 13

The method as described in example 12, wherein the configuration message includes a recommended time for the user equipment to exit the low-power connected mode and enter the Radio Resource Control connected mode.

### EXAMPLE 14

The method as described in any one of example 12 or example 13, wherein the recommended time comprises a duration of time or a recommended end time for the low-power connected mode.

### EXAMPLE 15

The method as described in any one of examples 12 to 14, wherein the configuration message instructs the user equipment to activate the low-power connected mode on a per-carrier basis based on at least one particular carrier identified in the request message.

### EXAMPLE 16

A base station comprising: a radio frequency transceiver for communicating with at least one user equipment; and a processor and memory system, coupled to the radio frequency transceiver configured to perform the method of any one of examples 12 to 15.

Although aspects of a low-power connected mode for wireless communication systems have been described in language specific to features and/or methods, the subject of the appended claims is not necessarily limited to the specific features or methods described. Rather, the specific features and methods are disclosed as example implementations of the low-power connected mode for wireless communication systems, and other equivalent features and methods are intended to be within the scope of the appended claims. Further, various different aspects are described, and it is to be appreciated that each described aspect can be implemented independently or in connection with one or more other described aspects.

1. A method of controlling operational modes in a user equipment, the method comprising:
detecting a thermal state or a battery state-of-charge of the user equipment while the user equipment is operating in a Radio Resource Control connected mode;
based on the thermal state or the battery state-of-charge, transmitting a request message to a base station for the user equipment to enter into a low-power connected mode, the request message identifying a particular carrier, the low-power connected mode enabling the user equipment to maintain a Radio Resource Control connection without monitoring a downlink channel for downlink signals from the base station;
receiving a configuration message from the base station to activate the low-power connected mode; and
activating the low-power connected mode for the particular carrier by the user equipment.

2. The method as described in claim 1, wherein transmitting the request message comprises transmitting the request message to the base station using a Radio Resource Control message, a medium access control-control element, or uplink control information.

3. The method as described in claim 1, wherein the request message is transmitted using an uplink carrier different from the particular carrier.

4. The method as described in claim 1, wherein activating the low-power connected mode comprises activating the low-power connected mode for the particular carrier while maintaining a Radio Resource Control connected mode using a second carrier.

5. The method as described in claim 1, wherein the request message indicates a duration of time for the low-power connected mode to be activated.

6. The method as described in claim 1, wherein the request message indicates an end-time for the low-power connected mode.

7. The method as described in claim 1 any one of further comprising:
transmitting a cancel message to exit the low-power connected mode and enter the Radio Resource Control connected mode.

8. The method as described in claim 7, wherein the cancel message is transmitted via a physical uplink control channel

9. The method as described in claim 7, wherein the cancel message is transmitted via a random access channel specific to the user equipment.

10. The method as described in claim 1, wherein the request message is transmitted using a supplementary uplink or a Long-Term Evolution Uplink.

11. (canceled)

12. A method for enabling user equipment-controlled connection modes, the method comprising:
receiving, by a base station, a request message from a user equipment operating in a Radio Resource Control connected mode, the request message requesting activation of a low-power connected mode for at least one particular carrier, the low-power connected mode comprising a low-power state of the Radio Resource Control connected mode in which the user equipment does not monitor for downlink signals from the base station;
generating, by the base station, a configuration message for the user equipment to activate the low-power connected mode for the particular carrier; and
transmitting, by the base station, the configuration message to the user equipment.

13. The method as described in claim 12, wherein the configuration message includes a recommended time for the user equipment to exit the low-power connected mode and enter the Radio Resource Control connected mode.

14. The method as described in claim 13, wherein the recommended time comprises a duration of time or a recommended end time for the low-power connected mode.

15. The method as described in claim 12, wherein the configuration message instructs the user equipment to activate the low-power connected mode on a per-carrier basis based on at least one particular carrier identified in the request message.

16. (canceled)

17. A user equipment comprising:
a radio frequency transceiver for communicating with a base station;
a temperature sensor for detecting a temperature of the user equipment; and
a processor and memory system, coupled to the radio frequency transceiver and the temperature sensor, that direct the user equipment to perform operations comprising:
detecting a thermal state or a battery state-of-charge of the user equipment while the user equipment is operating in a Radio Resource Control connected mode;
based on the thermal state or the battery state-of-charge, transmitting a request message to a base station for the user equipment to enter into a low-power connected mode, the request message identifying a particular carrier, the low-power connected mode enabling the user equipment to maintain a Radio Resource Control connection without monitoring a downlink channel for downlink signals from the base station;
receiving a configuration message from the base station to activate the low-power connected mode; and
activating the low-power connected mode for the particular carrier by the user equipment.

18. The user equipment as recited in claim 17, the operations further comprising:
transmitting a cancel message to exit the low-power connected mode and enter the Radio Resource Control connected mode.

19. The user equipment as recited in claim 17, wherein transmitting the request message comprises:
transmitting the request message using an uplink carrier different from the particular carrier.

20. The user equipment as recited in claim 17, wherein activating the low-power connected mode comprises:
activating the low-power connected mode for the particular carrier while maintaining a Radio Resource Control connected mode using a second carrier.

21. The user equipment as recited in claim 17, wherein transmitting the request message comprises:
indicating, with the request message, a duration of time for the low-power connected mode to be activated.

22. The user equipment as recited in claim 17, wherein transmitting the request message comprises:
indicating, with the request message, an end-time for the low-power connected mode.
